(19) United States
(12) Patent Application Publication
(10) Pub. No.: US 2026/0045299 A1
(43) Pub. Date: Feb. 12, 2026

(54) MEMORY DEVICE AND OPERATING METHOD THEREOF

(71) Applicant: TAIWAN SEMICONDUCTOR MANUFACTURING COMPANY, LTD., Hsinchu (TW)

(72) Inventor: Reiji MOCHIDA, Osaka (JP)

(73) Assignee: TAIWAN SEMICONDUCTOR MANUFACTURING COMPANY, LTD., Hsinchu (TW)

(21) Appl. No.: 18/796,550

(22) Filed: Aug. 7, 2024

(51) Int. Cl. G11C 13/00

(52) U.S. Cl. CPC G11C 13/0069; G11C 13/0028; G11C 13/0038; G11C 13/004; G11C 2013/0078

(57) ABSTRACT

A memory device is provided, including a memory array; a current limit circuit coupled to the memory array; and a write assist unit that generates a first voltage to the current limit circuit and controls, in response to a control signal, a second voltage coupled between the current limit circuit and the memory array. The current limit circuit transmits at least one write current flowing through the memory array in response to the first voltage and the second voltage.

### BACKGROUND

A type of non-volatile memory device using variable resistance has been developed, with each memory cell containing a memory element that can alter its resistance. This element can switch between high and low resistance states in response to electrical signals, enabling it to store data persistently. However, the write process requires a large voltage to change the resistance state of the memory element. Despite this, the device effectively maintains the stored information without power.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory device in accordance with some embodiments of the present disclosure.

FIG. 2 is a schematic diagram of part of the memory device corresponding to FIG. 1, in accordance with some embodiments of the present disclosure.

FIG. 3 illustrates waveforms of signals in the memory device corresponding to FIGS. 1-2, in accordance with some embodiments of the present disclosure.

FIG. 4 is a schematic diagram of part of the memory device corresponding to FIG. 1, in accordance with another embodiment of the present disclosure.

FIG. 5 is a schematic diagram of part of the memory device corresponding to FIG. 1, in accordance with another embodiment of the present disclosure.

FIG. 6 is a schematic diagram of part of the memory device corresponding to FIG. 1, in accordance with another embodiment of the present disclosure.

FIG. 7 is a schematic diagram of part of the memory device corresponding to FIG. 1, in accordance with another embodiment of the present disclosure.

FIG. 8 is a schematic diagram of part of the memory device corresponding to FIG. 1, in accordance with another embodiment of the present disclosure.

FIG. 9 is a flowchart diagram of a method for operating a memory device, in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. The term mask, photolithographic mask, photomask and reticle are used to refer to the same item.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

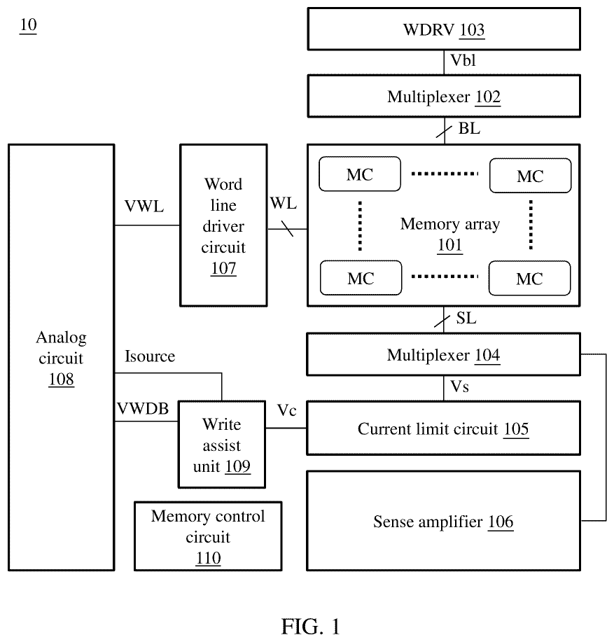

Reference is now made to FIG. 1. FIG. 1 is a schematic diagram of a memory device 10 in accordance with some embodiments of the present disclosure. In some embodiments, the memory device 10 is a nonvolatile semiconductor storage device For illustration, the memory device 10 includes a memory array 101, a multiplexer (MUX) 102, a write driver 103, a multiplexer 104, a current limit circuit 105, a sense amplifier 106, a word line driver circuit 107, an analog circuit 108, a write assist unit 109, a memory control circuit 110, multiple word lines WL, multiple bit lines BL as first data lines, multiple source lines as second data lines.

In some embodiments, the memory array 101 made up of multiple bitcells referred to as memory cells MC. The memory cells MC are at the intersection of a row with a column in the memory array 101. In some embodiments, the memory array 101 can be non-volatile memory array and includes resistive-based random access memory (RAM) cells. Resistive-based RAM can include resistive-RAM (ReRAM), magnetoresistive RAM (MRAM), ferroelectric RAM (FeRAM), dielectric RAM, any suitable array of any suitable memory devices, or combinations thereof. In some embodiments, the memory array 101 is configured to store multiple data in form of binary bit.

The multiplexer 102 is coupled between the memory array 101 and the write driver 103. The multiplexer 102 is configured to enable columns of the memory array 101 by selecting the bit line (BL) in response to received control signals (not shown) from the memory control circuit 110 and further to connect the selected bit line(s) BL to the write driver 103.

The write driver 103 is a circuit that applies a (write) voltage Vb1 to a memory cell MC in the memory array 101 to perform data write operation on the memory cell. In some embodiments, the write driver 103 applies a positive voltage supplied from the analog circuit 108, or a ground voltage, to the bit line BL that is selected by the multiplexer 102.

In some embodiments, the write driver 103 includes a bit line regulator that is a voltage generation circuit supplies the voltage Vb1 being applied to the bit line BL during data write operation on the memory cell MC. The bit line line regulator adjusts and outputs the voltage Vb1 according to the control signal from the memory control circuit 110.

The multiplexer 104 is coupled between the memory array 101 and the current limit circuit 105. The multiplexer 104 is configured to enable columns of the memory array 101 by selecting the source line (SL) in response to received control signals (not shown) from the memory control circuit 110 and further to connect the specified source line(s) SL to the current limit circuit 105.

In some embodiments, the multiplexer 104 includes precharge circuitry. For example, in memory access, the precharge circuitry precharges the source line SL for read operations.

The current limit circuit 105 is configured to transmit at least one write current Iw flowing through the memory array 101 in response to voltages Vs and Vc that are generated according to a control signal VWDB for the write operation of the memory cell MC. The configurations of the current limit circuit 105 will be discussed in detail in the following paragraphs.

The sense amplifier 106 is configured as a readout circuit to determine data stored in the memory cells MC during a read operation in response to a control signal from the memory control circuit 110. Specifically, the sense amplifier 106 is coupled to the memory array 101 through the multiplexer 104 in connection with the source lines SL. In operation, the multiplexer 104 selectively connects one of the source line SL to the sense amplifier 106 to read out data stored in the specified memory cell MC in the memory array 101.

The word line driver circuit (WLDR) 107 is configured to transmit word line signals VWL to drive word lines WL for accessing the memory array 101 to read/write bits from/into the memory array 101 in response to control signals associated with addresses, in which the addresses indicate some specific memory cells MC, storing bits, in the memory array 101. Specifically, in some embodiments, the word line driver circuit 107 selects and activates the specific memory cells MC in the memory array 101 according to the addresses.

In some embodiments, the analog circuit 108 generates, in response to control signals (not shown) from the memory control circuit 110, the control signal VWDB, the word line signals VWL, a current Isource, and bias voltages applied in the memory device 10 during memory access operations.

The write assist unit 109 is configured to generate the voltage Vc to the current limit circuit 105 and further configured to control, in response to the control signal VWDB, the voltage Vs coupled between the current limit circuit 105 and the memory array 101. The configurations of the current limit circuit 105 will be discussed in detail in the following paragraphs.

The memory control circuit 110 is configured to control the multiplexers 102, 104, the write driver 103, the current limit circuit 105, the sense amplifier 106, the word line driver circuit 107, the analog circuit 108, the write assist unit 109 to perform either traditional memory access (e.g., read and write of specific addresses.)

In some embodiments, the memory control circuit 110 includes an x-decoder for the word lines WL and a y-decoder for the bit lines BL and/or source lines SL. It also contains timing control for read and write operations. In some embodiments, the memory control circuit 110 is configured to generate control signals to the multiplexers 102, 104, the write driver 103, the current limit circuit 105, the sense amplifier 106, the word line driver circuit 107, the analog circuit 108, the write assist unit 109 for access operations (e.g., read operation and write operation to the memory array 101) in response to the addresses.

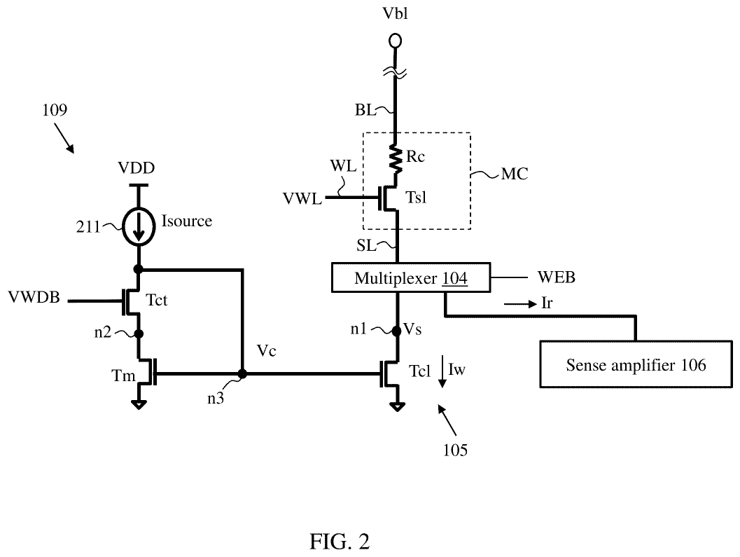

Reference is now made to FIG. 2. FIG. 2 is a schematic diagram of part of the memory device 10 corresponding to FIG. 1, in accordance with some embodiments of the present disclosure. With respect to the embodiments of FIG. 1, like elements in FIG. 2 are designated with the same reference numbers for ease of understanding. The specific operations of similar elements, which are already discussed in detail in above paragraphs, are omitted herein for the sake of brevity.

As shown in FIG. 2, one memory cell MC is given as example for illustration of the memory cells MC in the memory array 101, and is configured to receive the voltage Vb1 through the bit line BL. The memory cell MC is further coupled to the multiplexer 104 through the source line SL. In some embodiments, the memory cell MC includes a cell transistor Ts1 and a resistor Rc that are coupled in series between the bit line BL and the source line SL. Specifically, a gate terminal of the cell transistor Ts1 is coupled to a corresponding word line WL to receive the word line signal VWL, a drain/source terminal of the cell transistor Ts1 is coupled to the transistor Rc, and a source/drain terminal of the cell transistor Ts1 is coupled to the source line SL.

In some embodiments, a resistance of the resistor Rc indicates a data state stored in the memory cell MC. For example, a high resistance of the resistor Rc corresponds to “0” of the binary data, and a low resistance of the resistor Rc corresponds to “1” of the binary data.

In some embodiments, the multiplexer 104 selectively connects the source line SL to the current limit circuit 105 or the sense amplifier 106 in response to a control signal WEB from the memory control circuit 110. For example, when the control signal WEB indicates that the write operation is performed to the memory cell MC, the multiplexer 104 couples the source line SL to the current limit circuit 105 to transmit a corresponding write current Iw. When the control signal WEB indicates that the read operation is performed to the memory cell MC, the multiplexer 104 couples the source line SL to the sense amplifier 106.

In some embodiments, the current limit circuit 105 is coupled between the memory array 101 and a supply voltage terminal, for example, a ground. Specifically, the current limit circuit 105 includes a transistor Tel that has a drain/source terminal coupled to the memory cell MC through the multiplexer 104 and the source line SL at a node n1, and further has a source/drain terminal coupled to the ground.

As illustratively shown in FIG. 2, the write assist unit 109 includes a current source 211 and transistors Tm and Tct. The transistor Tm has a gate terminal coupled to a gate terminal of the transistor Tel and a source/drain terminal coupled to the ground. In some embodiments, the source/drain terminals of the transistors Tc1 and Tm are coupled with each other. A drain/source terminal of the transistor Tm is coupled to a source/drain terminal of the transistor Tct at a node n2. A drain/source terminal of the transistor Tct is coupled to a supply voltage terminal, for example, VDD, through the current source 211 and further coupled to the gate terminals of the transistors Tm and Tc1 at a node n3. A gate terminal of the transistor Tct is configured to receive the control signal VWDB. In some embodiments, a voltage level of the supply voltage terminal VDD is greater than the ground, and configured to be operational voltage of the memory device 10.

In some embodiments, the transistors Tct, Tm, and Tel are of the same conductivity type, for example, N-type. In some embodiments, the transistor Tct is of P-type and the transistors Tm and Tel are of N-type.

In some embodiments, a size, for example, a gate width, of the transistor Tct is greater than or at least equal to a size, for example, a gate width, of the transistor Tm. In such arrangement, the transistor Tm determines the value of the current Isource from the current source 211 transmitted through the transistor Tct.

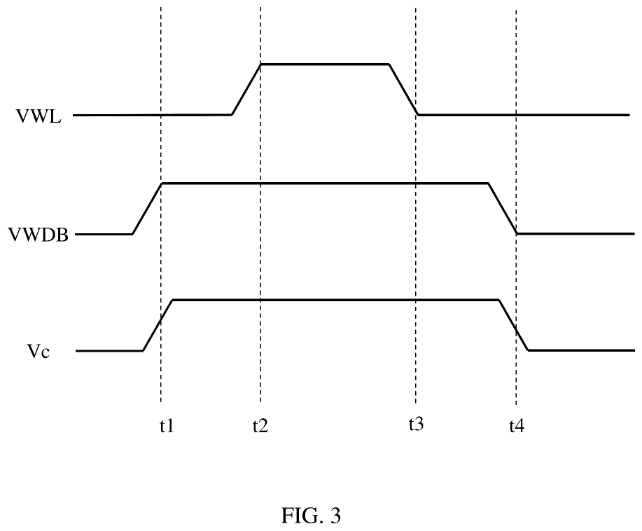

Reference is now made to FIGS. 2-3. FIG. 3 illustrates waveforms of signals in the memory device 10 corresponding to FIGS. 1-2, in accordance with some embodiments of the present disclosure.

During the write operation of the memory cell MC, at time t1 of FIG. 3, the write assist unit 109 is activated and the transistor Tct is configured to be turned on in response to the control signal VWDB rising before the memory cell is activated. The write assist unit 109 further generates the increasing voltage Vc at the node n3 while the current Isource flows through the transistors Tct and Tm.

At time t2, the memory cell MC is activated and the transistor Ts1 is turned on to receive the write current Iw in response to the rising word line signal VWL. Accordingly, the resistance state of the resistor Rc is adjusted based on the write current Iw and the corresponding data is written to the memory cell MC.

In some embodiments, a ratio of the current Isource over the write current Iw is associated a ratio of sizes of the transistors Tm and Tc1. In some embodiments, a ratio of the current Isource over the write current Iw is equal to a ratio of sizes of the transistors Tm and Tc1. For example, lengths of the transistors Tm and Tel are the same. A width W1 of the transistor Tel is double a width W2 of the transistor Tm. Accordingly, in the embodiments of the current Isource equal to a current value Iv, the write current Iw is equal to the double of the current value Iv.

In some embodiments, during the write operation, the write assist unit 109 controls the voltage Vs based on the control signal VWDB. In some embodiments, the highest voltage level of the control signal VWDB is smaller than the supply voltage provided by the supply voltage terminal VDD. Specifically, in some embodiments, a threshold voltage of the transistors Tc and Tc1 are the same, and the transistors Tm and Tc1 are configured as a current mirror to mirror the current Isource to the bit line BL and the source line SL. The voltage Vs at the node n1 equals to the voltage at the node n2, being the voltage level of the control signal VWDB minus the threshold voltage Vt of the transistor Tct (i.e., Vs=VWDB−Vt.) Alternatively stated, by adjusting the control signal VWDB, a desired voltage Vs is obtained in the write operation.

In some approaches of the non-volatile memory device, the variation of the write current has a large effect on the characteristics of the non-volatile memory, which is mitigated by applying high voltages to the memory device. However, it significantly affects the reliability of the memory cells and peripheral circuits. For example, in such arrangement, a voltage level at a bit line coupled to a memory cell, a voltage level at a source line coupled to a memory cell, and a voltage at a gate terminal of a current limit transistor coupled to the memory cell are around 2.0 Volts, 0.6 Volts, and 0.4 Volts respectively while a write current flowing through the memory cell is around 100 uA.

With the configurations of the present application, the voltage Vs on the source line SL is controlled by the transistor Tct in response to the control signal VWDB and is reduced to around 0.2 Volts, compared with some approaches, while the voltage Vb1 on the bit line BL decreases to around 1.6 Volts and the voltage Vc equal to around 0.7 Volts. Consequently, the voltages applied to the memory device 10 drop, which improves energy consumption of the memory device 10 and reliability of components of the memory device 10.

With reference to FIG. 3 again, at time t3, the word line signal VWL changes and the transistor Ts1 is turned off correspondingly to terminate write operation to the memory cell MC. After the memory cell MC is deactivated, the control signal VWDB drops to turn off the transistor Tct at time t4 and the voltage Vc goes down accordingly. Alternatively stated, as shown in FIG. 3, in the operation of the memory device 10, the word line signal VWL has a rising edge and a falling edge between a rising edge and a falling edge of the control signal VWDB.

In some embodiments, in a read operation the transistor Tct is configured to be turned off in response to the control signal VWDB, for example, having a ground voltage.

The configurations of FIGS. 1-3 are given for illustrative purposes. Various implements are within the contemplated scope of the present disclosure. For example, in some embodiments, the voltage values of the voltage Vc, Vb1, and Vs, values of the currents, and sizes of the transistors Tm, Tct, Tel are given for example.

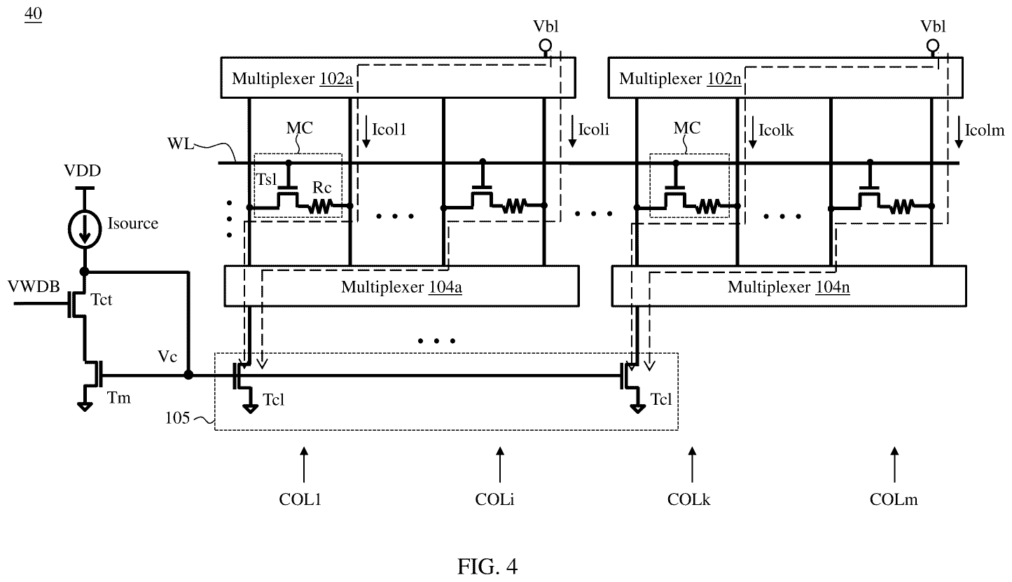

Reference is now made to FIG. 4. FIG. 4 is a schematic diagram of part of a memory device 40 corresponding to the memory device 10 of FIGS. 1-3, in accordance with another embodiment of the present disclosure. In some embodiments, the memory device 40 is configured with respect to, for example, the memory device 10. With respect to the embodiments of FIGS. 1-3, like elements in FIG. 4 are designated with the same reference numbers for ease of understanding.

In the embodiments of FIG. 4, memory cells MC in different columns are accessed in sequence. Specifically, the memory device 40 includes memory cells MC arranged in multiple columns COL1-COLm and multiplexers 102a-102n and 104a-104n, m and n being natural numbers. The current limit circuit 105 in the memory device 40 includes multiple transistors Tc1. In some embodiments, a first portion of memory cells MC are coupled to one of the transistors Tel and a second portion of the memory cells MC are coupled to another transistor Tel.

For example, as shown in FIG. 4, for a row of memory cells MC coupled to a single word line WL, the memory cells MC in the columns COL1-COLi are coupled to the multiplexers 102a and 104a and further to the one of the transistors Tel in the current limit circuit 105, and the memory cells MC in the columns COLk-COLm are coupled to the multiplexers 102n and 104n and further to another of the transistors Tel in the current limit circuit 105, i and k being a natural number smaller than m.

In some embodiments, during the write operation to the memory cells MC in the memory device 40, the memory cells MC are activated sequentially to transmit write currents to a corresponding transistor in the current limit circuit 105 through the source line SL, so that bit data are written into the memory cells MC sequentially. For example, in an embodiment of writing 2-bit data to the memory cells MC, firstly, the memory cell MC in the column COL1 coupled to the word line WL is activated to be accessed by a write current Icol1 associated with the voltage Vb1 and connected to one transistor Tc1 through the multiplexer 104a. Secondly, the memory cell MC in the column COL2, next to the column COL1, coupled to the word line WL is activated to be accessed by a write current Icol2 associated with the voltage Vb1 and connected to the one transistor Tc1 through the multiplexer 104a. In the embodiments of writing more than two bits of data to the memory cells MC, the multiplexers 104a-104n sequentially connect the accessed memory cell MC to the current limit circuit 105.

In some embodiments, all transistors Tel in the current limit circuit 105 are turned on at the same time during the write operation. For example, the transistor Tc1 coupled to the multiplexer 104a is turned on while one of the memory cells MC coupled to the multiplexer 104n is written.

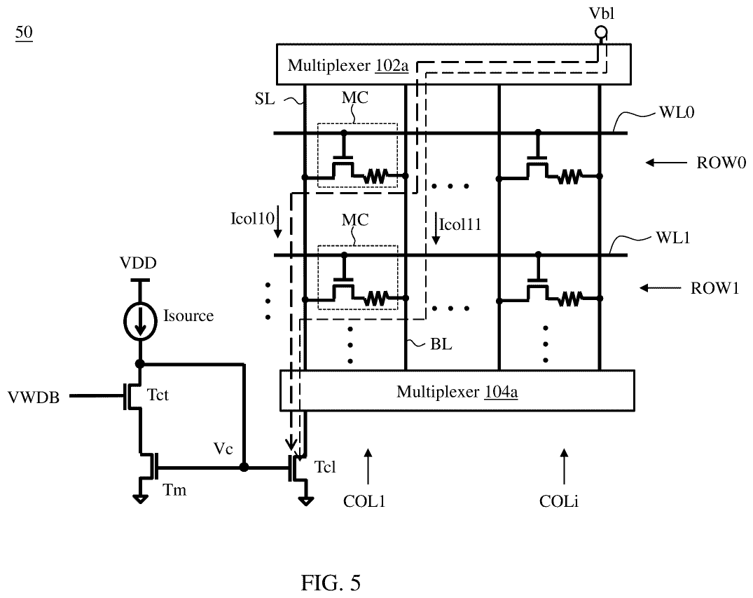

Reference is now made to FIG. 5. FIG. 5 is a schematic diagram of part of a memory device 50 corresponding to the memory device 10 of FIGS. 1-3, in accordance with another embodiment of the present disclosure. In some embodiments, the memory device 50 is configured with respect to, for example, the memory devices 10 and 40. With respect to the embodiments of FIGS. 1-4, like elements in FIG. 5 are designated with the same reference numbers for ease of understanding.

Compared with the embodiments in FIG. 4, in the embodiments of FIG. 5, memory cells MC in different rows are accessed in sequence.

For example, as shown in FIG. 5, for a column of memory cells MC coupled to the same bit line BL, the same source line SL, the same multiplexer 104a, and the same transistor Tel, the memory cells MC in the rows are coupled to different word lines, e.g., WL0-WL1.

In some embodiments of the write operation to the memory cells MC in the memory device 50, bit data are written into the memory cells MC sequentially. For example, in an embodiment of writing 2-bit data to the memory cells MC, firstly, the memory cell MC in a row ROW0 coupled to the word line WL0 is activated to be accessed by a write current Icol10 associated with the voltage Vb1 and connected to one transistor Tc1 through the multiplexer 104a. Secondly, the memory cell MC in a ROW1 coupled to the word line WL1 is activated to be accessed by a write current Icol11 associated with the voltage Vb1 and connected to the one transistor Tc1 through the multiplexer 104a. In the embodiments of writing more than two bits of data to the memory cells MC, the multiplexer 104a sequentially connects the accessed memory cell MC to the transistor Tc1.

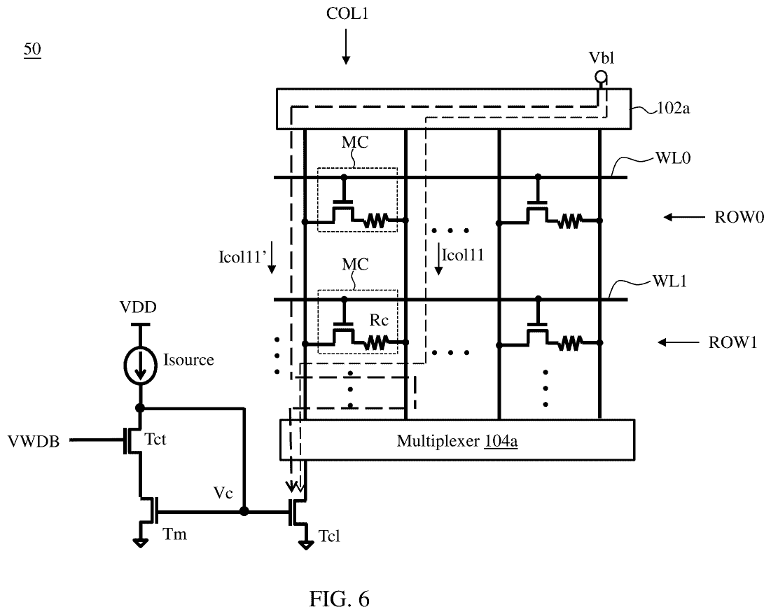

Reference is now made to FIG. 6. FIG. 6 is a schematic diagram of part of the memory device 50 corresponding to FIGS. 1 and 6, in accordance with another embodiment of the present disclosure.

In the first embodiment of FIG. 6 that the resistor Rc includes the first structure-composed of a top electrode coupled to the voltage Vb1, a first layer (e.g., tantalum pentoxide, Ta₂O₅), a second layer (e.g., tantalum oxide, TaOₓ) and a bottom electrode coupled to the transistor Ts1 in sequence, the memory cell MC is activated that the resistor Rc is written to have the high resistance state (corresponding to data “0”) by the write current Icol11 and is written to have the low resistance state (corresponding to data “1”) by the write current Icol11′.

In the second embodiment of FIG. 6 that the resistor Rc includes the second structure-composed of a top electrode coupled to the voltage Vb1, the second layer (e.g., tantalum oxide, TaOₓ), the first layer (e.g., tantalum pentoxide, Ta₂O₅) and a bottom electrode coupled to the transistor Ts1 in sequence, the memory cell MC is activated that the resistor Rc is written to have the high resistance state (corresponding to data “0”) by the write current Icol11′ and is written to have the low resistance state (corresponding to data “1”) by the write current Icol11.

The configurations of FIG. 6 are given for illustrative purposes. Various implements are within the contemplated scope of the present disclosure. For example, in some embodiments,

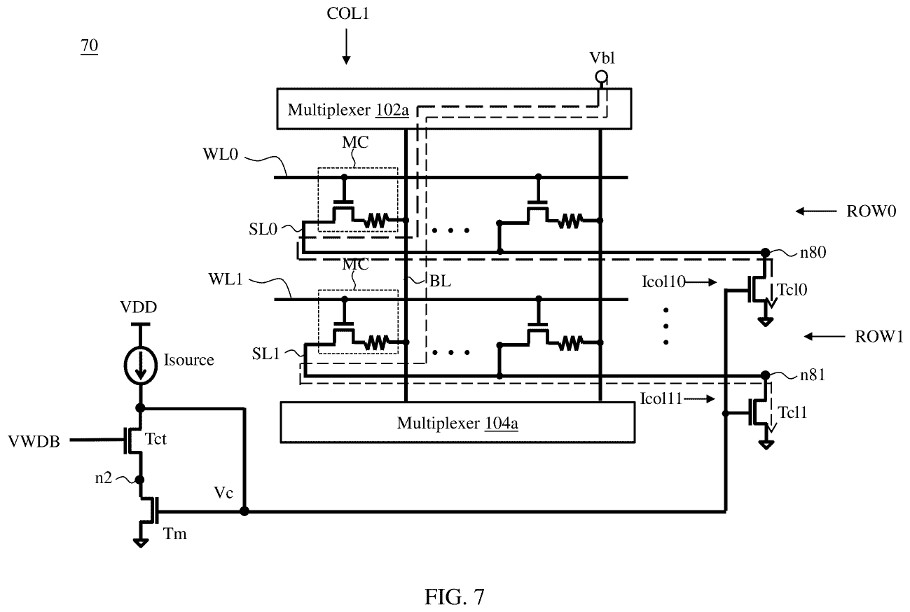

Reference is now made to FIG. 7. FIG. 7 is a schematic diagram of part of a memory device 70 corresponding to the memory device 10 of FIGS. 1-3, in accordance with another embodiment of the present disclosure. In some embodiments, the memory device 70 is configured with respect to, for example, the memory devices 10, 40 and 50. With respect to the embodiments of FIGS. 1-6, like elements in FIG. 7 are designated with the same reference numbers for ease of understanding.

As shown in FIG. 7, the current limit circuit 105 of the memory device 70 includes transistors Tc10-Tc11 that are configured with respect to, for example, the transistor Tc1. The gate terminals of the transistors Tc10-Tc11 are coupled to the gate terminal of the transistor Tm and the drain/source terminal of the transistor Tct to receive the voltage Vc.

In the embodiments of FIG. 7, memory cells MC in different rows and in the same column are accessed at the same time. Specifically, in the memory device 70 the memory cells MC in a same row are coupled to a same word line WL and a same transistor Tc1 through a same source line SL; whereas the memory cells MC in a same column are coupled to a same bit line BL.

For example, the memory cells MC in the row ROW0 are coupled to the word line WL0 and further to the transistor Tc10 through the source line SL0. The memory cells MC in the row ROW1 are coupled to the word line WL1 and further to the transistor Tell through the source line SL1. The memory cells MC in the column COL1 are coupled to the bit line BL and further to the multiplexer 104a.

In some embodiments, during the write operation to the memory cells MC in the memory device 70, the memory cells MC are activated at the same time to transmit write currents to transistors in the current limit circuit 105, so that bit data are written into the memory cells MC at the same time. For example, in an embodiment of writing 2-bit data to the memory cells MC, the transistor Tct is turned on in response to the control signal VWDB to generate the voltage Vc to to the transistors Tc10-Tc11. Then, the word lines WL0-WL1 are activated together to turn on the transistors Ts1 in the memory cells MC arranged in the column COL1 and the rows ROW0-ROW1.

Accordingly, the memory cell MC in the row ROW1 is activated to be accessed by the write current Icol10 that is associated with the voltage Vb1 and flows to the transistor Tc10 through the source line SL0. Meanwhile, the memory cell MC in the row ROW1 is activated to be accessed by the write current Icol11 that is associated with the voltage Vb1 and flows to the transistor Tell through the source line SL1

In some embodiments, the transistors Tc10-Tc11 are turned on at the same time during the write operation to transmit the write currents Icol10 and Icol11 respectively.

The configurations of FIG. 7 are given for illustrative purposes. Various implements are within the contemplated scope of the present disclosure. For example, in some embodiments, the memory device 70 includes more than two rows of memory cells MC that are configured with respect to, for example, the memory cells MC shown in FIG. 7.

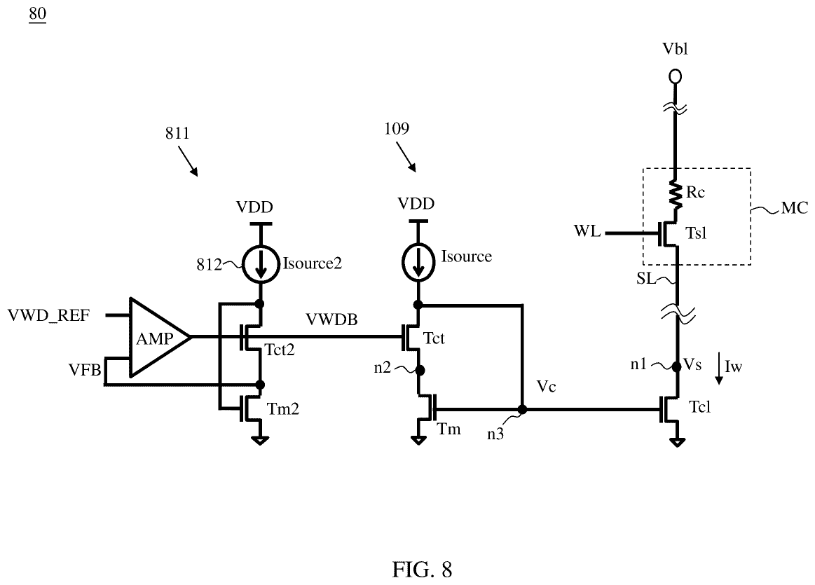

Reference is now made to FIG. 8. FIG. 8 is a schematic diagram of part of a memory device 80 corresponding to the memory device 10 of FIGS. 1-3, in accordance with another embodiment of the present disclosure. In some embodiments, the memory device 80 is configured with respect to, for example, the memory devices 10, 40, 50 and 70. With respect to the embodiments of FIGS. 1-7, like elements in FIG. 8 are designated with the same reference numbers for ease of understanding.

The analog circuit 108 in the memory device 80 further includes a voltage generator 811. The voltage generator 811 is configured to generate the control signal VWDB based on a reference voltage VWD_REF and a feedback voltage VFB that is associated with the control signal VWDB. Alternatively stated, the voltage generator 811 detects the feedback voltage VFB and adjusts the control signal VWDB according to the reference voltage VWD_REF and the feedback voltage VFB. the In some embodiments, the reference voltage VWD_REF is received from the memory control circuit 110 and equals to the voltage Vs. Alternatively stated, by controlling the reference voltage VWD_REF, the desired voltage Vs in write operation is obtained.

Specifically, as shown in FIG. 8, the voltage generator 811 includes an operational amplifier AMP and transistors Tct2 and Tm2. The transistors Tct2 and Tm2 are coupled in series between a current source 812 and the supply voltage terminal, for example, the ground. The current source 812 is configured to generate a current Isource2 and coupled to the supply voltage terminal VDD.

A gate terminal of the transistor Tm2 is coupled to the current source 812 and a drain/source terminal of the transistor Tct2, and a drain/source terminal of the transistor Tm2 is coupled to a source/drain terminal of the transistor Tct2.

The operational amplifier AMP has a first input coupled to the drain/source terminal of the transistor Tm2, a second input coupled to the reference voltage VWD_REF, and an output coupled to a gate terminal of the transistor Tct and the gate terminal of the transistor Tct.

In some embodiments of operation of the memory device 80, the operational amplifier compares the reference voltage VWD_REF and the feedback voltage VFB to generate the control signal VWDB to the transistor Tct. In some embodiments, the control signal VWDB is controlled so that the feedback voltage VFB equals to the reference voltage VWD_REF, the voltage at the node n2 and further to the voltage Vs. Accordingly, accurate voltage Vs is controlled by the voltage generator 811.

In some embodiments, a ratio of the current Isource2 over the current Isource is associated a ratio of sizes of the transistors Tm2 and Tm. In some embodiments, a ratio of the current Isource2 over the current Isource is equal to a ratio of sizes of the transistors Tm2 and Tm. For example, lengths of the transistors Tm2 and Tm are the same. A width of the transistor Tm is N times of a width of the transistor Tm2. Accordingly, in the embodiments of the current Isource2 equal to a current value Ivv, the current Isource is N times of the current value Ivv. Alternatively stated, the current Isource is N times greater than the current Isource2.

With reference to the relationship between the current Isource and the write current Iw, in some embodiments, when a ration of sizes of the transistors Tel and Tm equals to M and a ration of sizes of the transistors Tm and Tm2 equals to N, a ratio of the write current Iw over the current Isource2 equals to M times N. For example, in some embodiments, when M equals to 2 and N equals to 5, the currents Isource2, Isource and the write current equal to 10 uA, 50 uA, and 100 uA respectively.

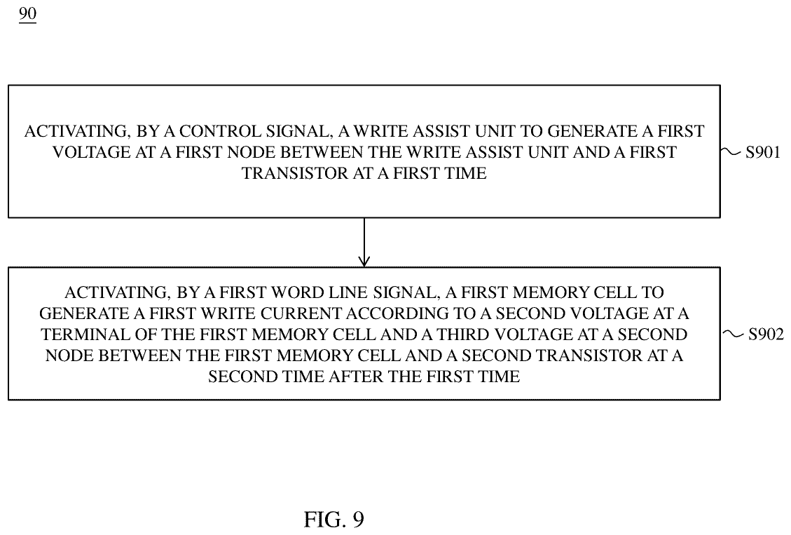

Reference is now made to FIG. 9. Reference is now made to FIG. 9. FIG. 9 is a flowchart diagram of a method 90 for operating a memory device corresponding to FIGS. 1-8, in accordance with some embodiments of the present disclosure. It is understood that additional operations can be provided before, during, and after the processes shown by FIG. 9, and some of the operations described below can be replaced or eliminated, for additional embodiments of the method 90. The order of the operations/processes may be interchangeable. Throughout the various views and illustrative embodiments, like reference numbers are used to designate like elements. The method 90 includes operations S901-S902 that are described below with reference to the memory device 10, 40, 50, 70, or 80 corresponding to FIGS. 1-8.

In operation S901, as shown in FIGS. 2-3, the write assist unit 109 is activated in response to the control signal VWDB to generate a voltage at the node n2 between the write assist unit 109 and the transistor Tm at time t1. Specifically, the transistor Tct in the write assist unit 109 is turned on in response to the control signal VWDB rising.

In operation S902, the memory cell MC is activated by the word line signal VWL on the word line WL, to generate the write current Iw according to the voltage Vb1 at a terminal of the memory cell MC and the voltage at node n1 between the memory cell MC and the transistor Tc1 at time t2 after time t1.

In some embodiments, the method 90 further includes operations of deactivating, by the word line signal VWL, the memory cell MC at time t3 after second time t2 and deactivating, by the control signal VWDB, the write assist unit 109 at time t4 after time t3, as shown in FIGS. 2-3.

In some embodiments, as shown in FIG. 7, in addition to operation S901 to activate the memory cell MC at the row ROW0 by the word line signal on the word line WL0 to transmit the current Icol10 according to the voltage Vb1 and the voltage at a node n80, the method 90 further includes operations of activating, by another word line signal on the word line WL1, the memory cell MC at the row ROW1 to generate another write current Icol11 according to the voltage Vb1 at a terminal of the memory cell MC and the voltage at a node n81 between the memory cell MC at the row ROW1 and the transistor Tell at time t2.

In some embodiments, the voltage level at the nodes n2, n80, and n81 are substantially the same with each other, for example, equal to the voltage level of the control signal VWDB minus the threshold voltage transistor Tct.

This application offers a memory device including a write assist unit to pull down voltages applied to the memory device in write operation. It improves energy consumption of the memory device and reliability of components of the memory device.

A memory device is provided, including a memory array; a current limit circuit coupled to the memory array; and a write assist unit that generates a first voltage to the current limit circuit and controls, in response to a control signal, a second voltage coupled between the current limit circuit and the memory array. The current limit circuit transmits at least one write current flowing through the memory array in response to the first voltage and the second voltage.

A method of operating a memory device is disclosed, including operations: activating, by a control signal, a write assist unit to generate a first voltage at a first node between the write assist unit and a first transistor at a first time; and activating, by a first word line signal, a first memory cell to generate a first write current according to a second voltage at a terminal of the first memory cell and a third voltage at a second node between the first memory cell and a second transistor at a second time after the first time.

A memory device is provided, including a first transistor and a second transistor that have gate terminals coupled with each other and first terminals coupled to a first voltage terminal; a first memory cell coupled between a first data line and a second terminal of the first transistor through a second data line; and a third transistor having: a first terminal coupled to the gate terminals of the first transistor and the second transistor and further coupled to a second voltage terminal through a first current source; and a second terminal coupled to a second terminal of the second transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a memory array;
a current limit circuit coupled to the memory array; and
a write assist unit configured to generate a first voltage to the current limit circuit and further configured to control, in response to a control signal, a second voltage coupled between the current limit circuit and the memory array,
wherein the current limit circuit is configured to transmit at least one write current flowing through the memory array in response to the first voltage and the second voltage.

2. The memory device of claim 1, wherein the current limit circuit comprises:
a first transistor coupled between a memory cell in the memory array and a first voltage terminal;
wherein the write assist unit comprises:
a second transistor having a gate terminal and a first terminal that are coupled to a gate terminal and a first terminal of the first transistor respectively; and
a third transistor having a first terminal coupled to a second terminal of the second transistor, a second terminal coupled to a second voltage terminal through a current source and the gate terminals of the first transistor and the second transistor, and a gate terminal to receive the control signal.

3. The memory device of claim 2, wherein the second voltage equals to a voltage of the control signal minus a threshold voltage of the third transistor.

4. The memory device of claim 2, wherein the first transistor to the third transistor are N-type transistors.

5. The memory device of claim 2, wherein the memory array comprises the memory cell configured to be activated to receive the write current in response to a word line signal,
wherein in a write operation of the memory cell the third transistor is configured to be turned on in response to the control signal before the memory cell is activated.

6. The memory device of claim 5, wherein the word line signal has a rising edge and a falling edge between a rising edge and a falling edge of the control signal.

7. The memory device of claim 5, wherein in a read operation the third transistor is configured to be turned off in response to the control signal.

8. The memory device of claim 1, wherein the memory array comprises a plurality of memory cells arranged in different rows,
wherein the current limit circuit comprises a transistor that is coupled to the plurality of memory cells through a source line and has a gate terminal configured to receive the first voltage,
wherein the plurality of memory cells are configured to be activated sequentially in write operation to transmit a plurality of the write currents to the transistor through the source line.

9. The memory device of claim 1, wherein the memory array comprises a plurality of memory cells coupled to a plurality of word lines,
wherein the current limit circuit comprises a plurality of transistors each coupled to a corresponding one of the plurality of memory cells that are arranged in the same column,
wherein cells in the plurality of memory cells are configured to be activated at the same time in write operation to transmit a plurality of the write currents to the plurality of transistors.

10. The memory device of claim 1, further comprising:
a voltage generator configured to generate the control signal based on a reference voltage and a feedback voltage that is associated with the control signal,
wherein the reference voltage equals to the second voltage.

11. A method, comprising:
activating, by a control signal, a write assist unit to generate a first voltage at a first node between the write assist unit and a first transistor at a first time; and
activating, by a first word line signal, a first memory cell to generate a first write current according to a second voltage at a terminal of the first memory cell and a third voltage at a second node between the first memory cell and a second transistor at a second time after the first time.

12. The method of claim 11, further comprising:
deactivating, by the first word line signal, the first memory cell at a third time after the second time; and
deactivating, by the control signal, the write assist unit at a fourth time after the third time.

13. The method of claim 11, further comprising:
activating, by a second word line signal, a second memory cell to generate a second write current according to the second voltage at a terminal of the second memory cell and a fourth voltage at a third node between the second memory cell and a third transistor at the second time.

14. The method of claim 13, wherein the first voltage, the third voltage, and the fourth voltage are substantially the same with each other.

15. A memory device, comprising:
a first transistor and a second transistor that have gate terminals coupled with each other and first terminals coupled to a first voltage terminal;
a first memory cell coupled between a first data line and a second terminal of the first transistor through a second data line; and
a third transistor having:
a first terminal coupled to the gate terminals of the first transistor and the second transistor and further coupled to a second voltage terminal through a first current source; and
a second terminal coupled to a second terminal of the second transistor.

16. The memory device of claim 15, wherein the first to third transistors are of a same conductivity type.

17. The memory device of claim 16, wherein a size of the third transistor is larger or equal to a size of the second transistor.

18. The memory device of claim 16, further comprising:
a fourth transistor and a fifth transistor that are coupled in series between a second current source and the first voltage terminal,
wherein a gate terminal of the fourth transistor is coupled to the second current source and a first terminal of the fifth transistor, and a first terminal of the fourth transistor is coupled to a second terminal of the fifth transistor; and
an amplifier having a first input coupled to the first terminal of the fourth transistor, a second input coupled to a reference voltage, and an output coupled to a gate terminal of the fifth transistor and a gate terminal of the third transistor.

19. The memory device of claim 18, wherein a current value of the first current source is greater than a current value of the second current source.

20. The memory device of claim 16, further comprising:
a fourth transistor having a gate terminal coupled to the gate terminals of the first transistor and the second transistor and a first terminal coupled to the first voltage terminal; and
a second memory cell coupled between the first data line and the fourth transistor,
wherein the first memory cell is coupled to a first word line, and the second memory cell is coupled to a second word line different from the first word line.
